(19) United States
(12) Patent Application Publication
(10) Pub. No.: US 2021/0057561 A1
(43) Pub. Date: Feb. 25, 2021

(54) HIGH ELECTRON MOBILITY TRANSISTOR DEVICE AND METHODS FOR FORMING THE SAME

(71) Applicant: Vanguard International Semiconductor Corporation, Hsinchu (TW)

(72) Inventors: Chi-Feng HSIEH, Taipei City (TW); Tuan-Wei WANG, New Taipei City (TW); Chien-Jen SUN, Jhubei City (TW)

(73) Assignee: Vanguard International Semiconductor Corporation, Hsinchu (TW)

(21) Appl. No.: 16/545,155

(22) Filed: Aug. 20, 2019

(51) Int. Cl. H01L 29/778; H01L 29/15; H01L 29/06; H01L 29/205; H01L 29/66; H01L 21/02

(52) U.S. Cl. CPC H01L 29/7787; H01L 29/155; H01L 29/0684; H01L 21/0254; H01L 29/66462; H01L 21/02507; H01L 29/205

(57) ABSTRACT

A high electron mobility transistor device includes a substrate, a superlattice buffer layer, a gradient buffer layer and a channel layer. The superlattice buffer layer are disposed over the substrate, wherein the superlattice buffer layer includes a plurality of sets of alternating layers, and each set of alternating layers includes at least one AlN layer and at least one AlₓGa₍₁₋ₓ₎N layer alternately arranged, wherein 0≤x<1. The gradient buffer layer is disposed over the substrate, wherein the gradient buffer layer includes a plurality of Al_{y}Ga_{(1-y)}N layers, wherein 0≤y<1. The channel layer is disposed over the gradient buffer layer.

### BACKGROUND

### Technical Field

The embodiment of the present disclosure relates to semiconductor manufacturing, and in particular it relates to high electron mobility transistor devices and methods for forming the same.

### Description of the Related Art

A high electron mobility transistor (HEMT), also known as a heterostructure field-effect transistor (HFET) or a modulation-doped field-effect transistor (MODFET), is a kind of field effect transistor (FET) made of semiconductor materials having different energy gaps. A two-dimensional electron gas (2DEG) layer is formed at the interface between two different semiconductor materials that are adjacent to each other. Due to the high electron mobility of the 2DEG, the HEMT device can have a high breakdown voltage, high electron mobility, low on-resistance, low input capacitance, and other advantages, and is therefore suitable for high-power components.

However, since the material of the substrate and the material of the semiconductor layer are different, there are problems such as lattice mismatch and different thermal expansion coefficients between the two, which can easily cause structural deformation in the HEMTs. Thus, a buffer layer is provided between the substrate and the semiconductor layer to relieve the structural deformation and its possible defects. In order to improve the existing HEMTs in various aspects, such as forming a semiconductor layer with better crystal qualities and reducing the manufacturing cost, it is necessary to continuously improve the setting of the buffer layer.

### BRIEF SUMMARY

In accordance with some embodiments of the present disclosure, a high electron mobility transistor (HEMT) device is provided. The HEMT device includes a substrate; a superlattice buffer layer disposed over the substrate, wherein the superlattice buffer layer includes a plurality of sets of alternating layers, and each set of alternating layers includes at least one AlN layer and at least one AlₓGa₍₁₋ₓ₎N layer alternately arranged, wherein 0≤x<1; a gradient buffer layer disposed over the substrate, wherein the gradient buffer layer includes a plurality of Al_{y}Ga_{(1-y)}N layers, wherein 0≤y<1; and a channel layer disposed over the gradient buffer layer.

In some embodiments, the AlₓGa₍₁₋ₓ₎N layers have the same x value in each set of alternating layers.

In some embodiments, the AlₓGa₍₁₋ₓ₎N layers have different x values for different sets of alternating layers.

In some embodiments, the x values of the AlₓGa₍₁₋ₓ₎N layers of the set of alternating layers adjacent to the substrate are greater than the x values of the AlₓGa₍₁₋ₓ₎N layers of the set of alternating layers away from the substrate.

In some embodiments, the thickness of the AlN layer ranges from 1 nm to 20 nm and the thickness of the AlₓGa₍₁₋ₓ₎N layer ranges from 5 nm to 100 nm in each set of alternating layers.

In some embodiments, the ratio of the thickness of the AlₓGa₍₁₋ₓ₎N layer to the thickness of the AlN layer ranges from 3 to 10.

In some embodiments, the thickness of each of the Al_{y}Ga_{(1-y)}N layers ranges from 50 nm to 500 nm.

In some embodiments, the y value of the Al_{y}Ga_{(1-y)}N layer adjacent to the substrate is greater than the y value of the Al_{y}Ga_{(1-y)}N layer away from the substrate.

In some embodiments, the gradient buffer layer is disposed over the superlattice buffer layer.

In some embodiments, the HEMT device further includes a nucleation layer disposed between the substrate and the superlattice buffer layer, wherein the nucleation layer includes aluminum nitride (AlN), aluminum gallium nitride (AlGaN), or a combination thereof.

In some embodiments, the HEMT device further includes a barrier layer disposed over the channel layer; and a source, a drain, a gate disposed over the barrier layer.

In accordance with another embodiment of the present disclosure, a method for forming high electron mobility transistor devices is provided. The method includes forming a substrate; forming a superlattice buffer layer over the substrate, wherein the superlattice buffer layer includes a plurality of sets of alternating layers, and each set of alternating layers includes at least one AlN layer and at least one AlₓGa₍₁₋ₓ₎N layer alternately arranged, wherein 0≤x<1; forming a gradient buffer layer over the substrate, wherein the gradient buffer layer includes a plurality of Al_{y}Ga_{(1-y)}N layers, wherein 0≤y<1; and forming a channel layer over the gradient buffer layer.

In some embodiments, the AlₓGa₍₁₋ₓ₎N layers have the same x value in each set of alternating layers.

In some embodiments, the AlₓGa₍₁₋ₓ₎N layers have different x values for different sets of alternating layers.

In some embodiments, the x values of the AlₓGa₍₁₋ₓ₎N layers of the set of alternating layers adjacent to the substrate are greater than the x values of the AlₓGa₍₁₋ₓ₎N layers of the set of alternating layers away from the substrate.

In some embodiments, in each set of alternating layers, the thickness of the AlN layer ranges from 1 nm to 20 nm, the thickness of the AlₓGa₍₁₋ₓ₎N layer ranges from 5 nm to 100 nm, and the ratio of the thickness of the AlₓGa₍₁₋ₓ₎N layer to the thickness of the AlN layer ranges from 3 to 10.

In some embodiments, the thickness of each of the Al_{y}Ga_{(1-y)}N layers ranges from 50 nm to 500 nm.

In some embodiments, the y value of the Al_{y}Ga_{(1-y)}N layer adjacent to the substrate is greater than the y value of the Al_{y}Ga_{(1-y)}N layer away from the substrate.

In some embodiments, the gradient buffer layer is formed over the superlattice buffer layer.

In some embodiments, the method further includes forming a nucleation layer between the substrate and the superlattice buffer layer, wherein the nucleation layer includes aluminum nitride (AlN), aluminum gallium nitride (AlGaN), or a combination thereof.

### BRIEF DESCRIPTION OF THE DRAWINGS

The disclosure can be more fully understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1-5 are cross-sectional views illustrating a high electron mobility transistor device at various stages of manufacture in accordance with some embodiments.

### DETAILED DESCRIPTION

The following outlines several embodiments so that those skilled in the art may better understand the present disclosure. However, these embodiments are examples only and are not intended to limit the present disclosure. It is understandable that those skilled in the art may adjust the embodiments described below according to requirements, for example, changing the order of processes and/or including more or fewer steps than described herein. Furthermore, other elements may be added on the basis of the embodiments described below. For example, the description of “forming a second element on a first element” may include embodiments in which the first element is in direct contact with the second element, and may also include embodiments in which additional elements are disposed between the first element and the second element such that the first element and the second element are not in direct contact, and spatially relative descriptors of the first element and the second element may change as the device is operated or used in different orientations.

In accordance with some embodiments of the present disclosure, a superlattice buffer layer and a gradient buffer layer are provided between a substrate and a channel layer of a high electron mobility transistor (HEMT) device to improve the performance and yield of the HEMT device while improving productivity.

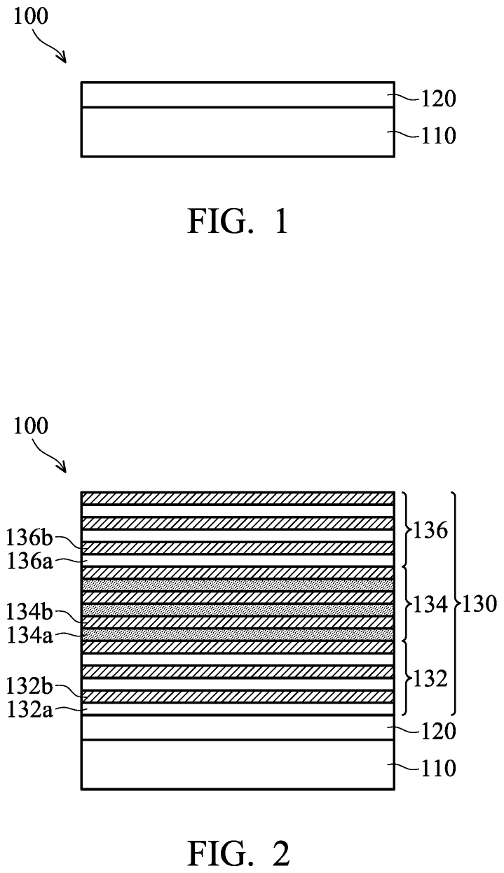

FIGS. 1-5 are cross-sectional views illustrating a HEMT device 100 at various stages of manufacture in accordance with some embodiments. As illustrated in FIG. 1, the HEMT device 100 includes a substrate 110. The substrate 110 may be a bulk semiconductor substrate or a composite substrate formed of different materials. The substrate 110 may include any substrate materials suitable for semiconductor devices, such as silicon, germanium, silicon carbide, gallium nitride (GaN), and/or sapphire.

In some embodiments, a nucleation layer 120 is formed over the substrate 110 to relieve the lattice mismatch between the substrate 110 and layers grown thereon. For example, the nucleation layer 120 may include aluminum nitride (AlN), aluminum gallium nitride (AlGaN), the like, or a combination thereof, and the thickness of the nucleation layer 120 may range from about 100 nanometers (nm) to about 1000 nm, such as about 200 nm. The nucleation layer 120 may be formed by a deposition process, such as metal organic chemical vapor deposition (MOCVD), molecular beam epitaxy (MBE), liquid phase epitaxy (LPE), or another deposition process.

In some embodiments, as illustrated in FIG. 2, a superlattice buffer layer 130 is formed over the nucleation layer 120. The nucleation layer 120 is optional. In other embodiments, the superlattice buffer layer 130 may be formed directly on the substrate without providing the nucleation layer 120. The superlattice buffer layer 130 may be formed by a deposition process, such as MOCVD, MBE, LPE, the like, or a combination thereof.

The superlattice buffer layer 130 includes a plurality of sets of alternating layers. For example, in the embodiment illustrated in FIG. 2, the superlattice buffer layer 130 includes a first set of alternating layers 132 closest to the substrate, a second set of alternating layers 134, and a third set of alternating layers 136 furthest from the substrate. Each of the alternating layers includes at least one aluminium nitride (AlN) layer and at least one aluminium gallium nitride (AlₓGa₍₁₋ₓ₎N) layer alternately arranged, wherein the aluminum gallium nitride may be represented by AlₓGa₍₁₋ₓ₎N, wherein 0≤x<1, in accordance with different aluminum contents. As illustrated in FIG. 2, the first set of alternating layers 132 includes three AlₓGa₍₁₋ₓ₎N layers 132a and three AlN layers 132b alternately arranged, the second set of alternating layers 134 includes three AlₓGa₍₁₋ₓ₎N layers 134a and three AlN layers 134b alternately arranged, and the third set of alternating layers 136 includes three AlₓGa₍₁₋ₓ₎N layers 136a and three AlN layers 136b alternately arranged.

Although in the embodiment illustrated in FIG. 2, the superlattice buffer layer 130 includes the first set of alternating layers 132, the second set of alternating layers 134, and the third set of alternating layers 136, and each of the alternating layers includes three sets of AlₓGa₍₁₋ₓ₎N layer and AlN layer alternately arranged, but the number of alternating layers and/or the number of AlₓGa₍₁₋ₓ₎N layer and AlN layer may be increased or decreased as needed, and for different sets of alternating layers, each set of alternating layers may have different number of AlₓGa₍₁₋ₓ₎N layers and AlN layers alternately arranged.

In each set of alternating layers, the x values of the AlₓGa₍₁₋ₓ₎N layers are the same, while for different sets of alternating layers, the x values of the AlₓGa₍₁₋ₓ₎N layers are different. That is, the AlₓGa₍₁₋ₓ₎N layers having the same aluminum content are the same set of alternating layers. Furthermore, the x value of the AlₓGa₍₁₋ₓ₎N layer of the set of alternating layers adjacent to the substrate is greater than the x value of the AlₓGa₍₁₋ₓ₎N layer of another set of alternating layers away from the substrate. In other words, the AlₓGa₍₁₋ₓ₎N layer of the set of alternating layers closest to the substrate has the largest aluminum content and the aluminum content decreases substantially as the alternating layers away from the substrate.

In addition, the value of x, that is, the aluminum content in the AlₓGa₍₁₋ₓ₎N layer, may be adjusted as needed. For example, in the embodiment illustrated in FIG. 2, the x value of the AlₓGa₍₁₋ₓ₎N layer 132a of the first set of alternating layers 132 is about 0.75, the x value of the AlₓGa₍₁₋ₓ₎N layer 134a of the second set of alternating layers 134 is about 0.5, and the x value of the AlₓGa₍₁₋ₓ₎N layer 136a of the third set of alternating layers 136 is about 0.25, so the AlₓGa₍₁₋ₓ₎N layers 132a, 134a, and 136a may also be referred to as an Al_{0.75}Ga_{0.25}N layer, an Al_{0.5}Ga_{0.5}N layer and an Al_{0.25}Ga_{0.75}N layer, respectively.

In accordance with some embodiments, in each set of alternating layers, the thickness of the AlₓGa₍₁₋ₓ₎N layer may range from about 5 nm to about 100 nm, and the thickness of the AlN layer may range from about 1 nm to about 20 nm. For example, the thickness of the AlₓGa₍₁₋ₓ₎N layer is about 20 nm, and the thickness of the AlN layer is about 5 nm. In some embodiments, the ratio of the thickness of the AlₓGa₍₁₋ₓ₎N layer to the thickness of the AlN layer may range from about 3 to about 10. Although the first set of alternating layers 132, the second set of alternating layers 134 and the third set of alternating layers 136, and the AlₓGa₍₁₋ₓ₎N layers 132a, 134a, 136a and AlN layers 132b, 134b, 136b in these alternating layers have the same thickness as illustrated in FIG. 2, the present disclosure is not limited thereto. The thickness of each set of alternating layers and/or the thickness of the AlₓGa₍₁₋ₓ₎N layers and the AlN layers alternately arranged may be adjusted as needed, and for different sets of alternating layers, the AlₓGa₍₁₋ₓ₎N layer and the AlN layer alternately arranged may each have different thicknesses. In some embodiments, the thickness of the superlattice buffer layer 130 may range from about 0.05 micrometers (μm) to about 10 μm, such as about 0.2 μm.

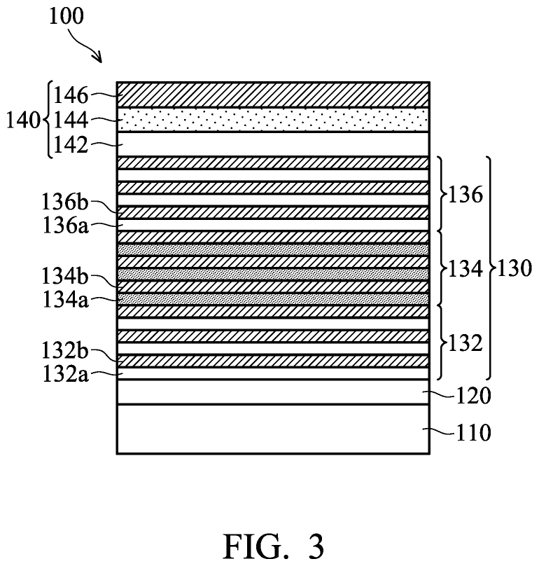

As illustrated in FIG. 3, in some embodiments, a gradient buffer layer 140 is formed over the superlattice buffer layer 130. The gradient buffer layer 140 may be formed by a deposition process, such as MOCVD, MBE, LPE, or other deposition process. The gradient buffer layer 140 may include a plurality of aluminum gallium nitride (Al_{y}Ga_{(1-y)}N) layers, and may be represented by Al_{y}Ga_{(1-y)}N, wherein 0≤y<1, in accordance with different aluminum contents. The y value of the Al_{y}Ga_{(1-y)}N layer adjacent to the substrate is greater than the y value of the Al_{y}Ga_{(1-y)}N layer away from the substrate. In other words, the Al_{y}Ga_{(1-y)}N layer closest to the substrate has the largest aluminum content, and the aluminum content decreases substantially as the Al_{y}Ga_{(1-y)}N layer away from the substrate.

In the embodiment illustrated in FIG. 3, the gradient buffer layer 140 includes a first Al_{y}Ga_{(1-y)}N layer 142 closest to the substrate, a second Al_{y}Ga_{(1-y)}N layer 144 and a third Al_{y}Ga_{(1-y)}N layer 146 away from the substrate. The number of Al_{y}Ga_{(1-y)}N layers may be increased or decreased as needed, and the y value, that is, the aluminum content in the Al_{y}Ga_{(1-y)}N layer, may be adjusted. For example, in the embodiment illustrated in FIG. 3, the y value of the first Al_{y}Ga_{(1-y)}N layer 142 is about 0.75, the y value of the second Al_{y}Ga_{(1-y)}N layer 144 is about 0.5, and the y value of the third Al_{y}Ga_{(1-y)}N layer 146 is about 0.25, so the first Al_{y}Ga_{(1-y)}N layer 142, the second Al_{y}Ga_{(1-y)}N layer 144, and the third Al_{y}Ga_{(1-y)}N layer 146 may also be referred to as an Al_{0.75}Ga_{0.25}N layer, an Al_{0.5}Ga_{0.5}N layer, and an Al_{0.25}Ga_{0.75}N layer, respectively.

In accordance with some embodiments, the thickness of the Al_{y}Ga_{(1-y)}N layer may range from about 50 nm to about 500 nm, such as about 100 nm. Although the first Al_{y}Ga_{(1-y)}N layer 142, the second Al_{y}Ga_{(1-y)}N layer 144, and the third Al_{y}Ga_{(1-y)}N layer 146 have the same thickness as illustrated in FIG. 3, the present disclosure is not limited thereto, and the thickness of each layer of the Al_{y}Ga_{(1-y)}N layers may be adjusted as needed. In some embodiments, the thickness of the gradient buffer layer 140 may range from about 0.1 μm to about 10 μm, such as about 0.3 μm.

Although the thickness of the superlattice buffer layer 130 is greater than the thickness of the gradient buffer layer 140 as illustrated in FIG. 3, the present disclosure is not limited thereto, and the thickness of the superlattice buffer layer 130 and the thickness of the gradient buffer layer 140 may be adjusted as needed. In some embodiments, the total thickness of the superlattice buffer layer 130 and the gradient buffer layer 140 may range from about 0.1 μm to about 10 μm, such as about 0.3 μm. In some embodiments, the ratio of the thickness of the superlattice buffer layer 130 to the thickness of the gradient buffer layer 140 may range from about 0.2 to about 2, such as about 0.75.

In accordance with some embodiments of the present disclosure, the superlattice buffer layer 130 and the gradient buffer layer 140 are disposed over the substrate 110 of the HEMT device 100 to relieve the lattice mismatch between the substrate 110 and the layer formed thereon, thereby avoiding forming defects such as bows or cracks caused by the lattice mismatch between the substrate 110 and the layer when forming the layer, so that the yield of the HEMT device 100 can be improved.

In addition, since the forming time of the gradient buffer layer 140 is shorter than the forming time of the superlattice buffer layer 130, for forming the buffer layer with the same thickness over the substrate 110, forming the buffer layer including the superlattice buffer layer 130 and the gradient buffer layer 140 in accordance with some embodiments of the present disclosure can significantly shorten the forming time and increase the productivity of the HEMT device 100 as compared to forming the superlattice buffer layer 130 only.

On the other hand, the gradient buffer layer 140 is less effective in relieving the lattice mismatch than the superlattice buffer layer 130. For forming a buffer layer with the same thickness over the substrate, forming a buffer layer including the superlattice buffer layer 130 and the gradient buffer layer 140 on the substrate can form a layer with better crystal qualities thereon, as compared to forming the gradient buffer layer 140 only, thereby the thickness of the layer such as a channel layer can be increased, in accordance with some embodiments of the present disclosure.

In addition, in accordance with some embodiments of the present disclosure, a superlattice buffer layer 130 is first disposed on the substrate 110 of the HEMT device 100, then a gradient buffer layer 140 is disposed, and the superlattice buffer layer 130 underlying can prevent the dislocation in the substrate 110 from entering the layer formed over the gradient buffer layer 140, and compared to forming the gradient buffer layer 140 and then forming the superlattice buffer layer 130, the layer formed thereon can have better crystalline qualities.

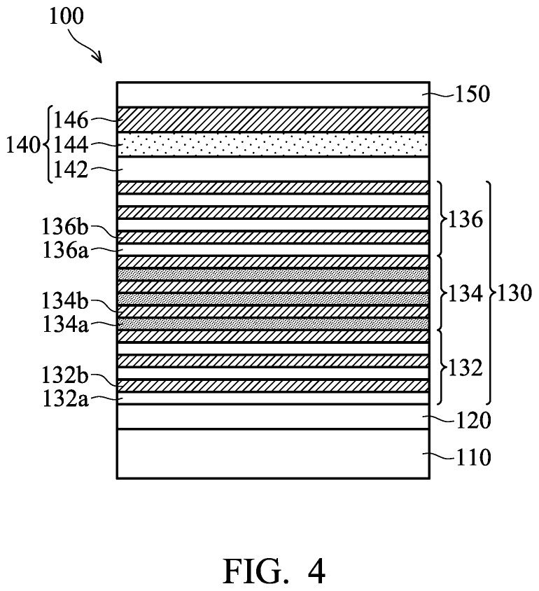

Then, as illustrated in FIG. 4, a channel layer 150 is formed over the gradient buffer layer 140. In some embodiments, a material of the channel layer 150 may include a group III nitride, such as a III-V compound semiconductor material. In some embodiments, the material of the channel layer 150 may include gallium nitride (GaN). The channel layer 150 may be doped or undoped as needed. The channel layer 150 may be formed by a deposition process, such as MOCVD, MBE, LPE, or other deposition process. The thickness of the channel layer 150 may be adjusted as needed. For example, in some embodiments, the thickness of the channel layer 150 may range from about 10 nm to about 1000 nm, such as about 200 nm.

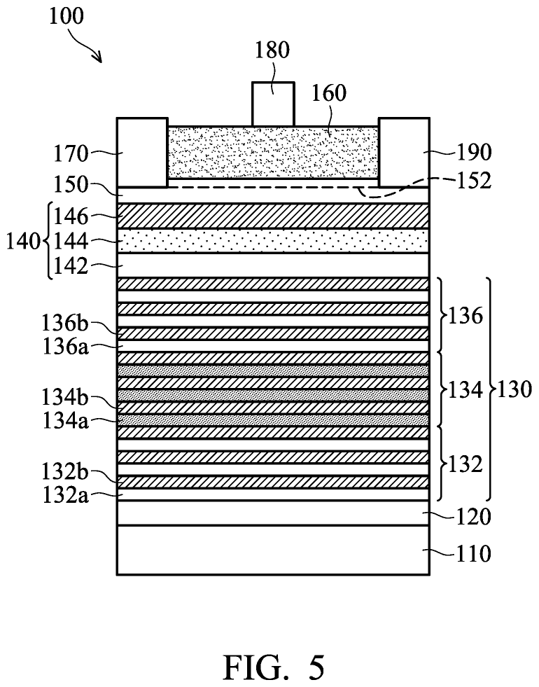

Then, as illustrated in FIG. 5, a barrier layer 160 is formed over the channel layer 150. The barrier layer 160 may be formed by a deposition process, such as MOCVD, MBE, LPE, or another deposition process. In some embodiments, the barrier layer 160 may include a group III nitride, such as a group III-V compound semiconductor material. The barrier layer 160 may include a single layer or a multilayer structure. For example, the barrier layer 160 may include AN, AlGaN, AlInN, AlGaInN, the like, or a combination thereof. The barrier layer 160 may be doped or undoped as needed. The material of the channel layer 150 and the material of the barrier layer 160 may be chosen to create a 2DEG 152 at the interface between the channel layer 150 and the barrier layer 160.

Then, a source 170, a gate 180, and a drain 190 are disposed over the barrier layer 160 to form the HEMT device 100, in accordance with some embodiments. The source 170, the gate 180, and the drain 190 may be formed by using any suitable material, process, and sequence, and the spacing and location may be adjusted as needed. In the embodiment illustrated in FIG. 5, the source 170 and the drain 190 pass through the barrier layer 160 into the channel layer 150, and the gate 180 is on the surface of the barrier layer 160, in accordance with some embodiments, but the present disclosure not limited thereto, there may be other arrangements or configurations. For example, a p-type doped gallium nitride (p-GaN) layer may be disposed between the gate 180 and the barrier layer 160 such that the gate 180 is not in contact with the barrier layer 160, and the HEMT device 100 is an enhancement mode (E-mode) element; or, a p-type doped gallium nitride (p-GaN) layer is not disposed between the gate 180 and the barrier layer 160, and the HEMT device 100 is a depletion mode (D-mode) element.

In general, when forming a channel layer of a HEMT device, since there is a lattice mismatch between the channel layer and the substrate, defects such as cracks or bows are easily formed in the channel layer. These defects become severe as the thickness of the channel layer increases, affecting the performance of the HEMT device, and thus the thickness of the channel layer is limited. Some embodiments of the present disclosure provide a superlattice buffer layer and a gradient buffer layer between the substrate and the channel layer of the HEMT device, and adjust the aluminum content in the superlattice buffer layer and the gradient buffer layer, which can relieve the lattice mismatch between the substrate and the channel layer formed thereon, reduce the defects caused thereby, improve the crystal quality of the channel layer, thereby can further increasing the thickness of the channel layer to improve the performance and the productivity of the HEMT device.

In addition, the gradient buffer layer has a shorter forming time than the superlattice buffer layer, but its effect of avoiding defects in the channel layer is not as good as that of the superlattice buffer layer. Therefore, for forming a buffer layer with the same thickness, forming a buffer layer including a superlattice buffer layer and a gradient buffer layer over the substrate in accordance with some embodiments of the present disclosure, compared to forming a superlattice buffer layer only, the forming time can be significantly shortened, so that the productivity of the HEMT device can be increased; on the other hand, compared to forming the gradient buffer layer only, a channel layer with a better crystalline quality can be formed on these buffer layer, thereby the yield of the HEMT can be improved.

Furthermore, in accordance with some embodiments of the present disclosure, a superlattice buffer layer is disposed over the substrate of the HEMT device, and then a gradient buffer layer is disposed, which can effectively prevent the dislocation in the substrates from entering the channel layer and can further improve the crystalline quality of the channel layer. Therefore, some embodiments of the present disclosure can improve the performance and the yield of the HEMT device while improving the productivity.

While the present disclosure has been described above by various embodiments, these embodiments are not intended to limit the present disclosure. Those skilled in the art should appreciate that they may make various changes, substitutions and alterations based on the embodiments of the present disclosure to realize the same purposes and/or advantages as the various embodiments described herein. Those skilled in the art should also appreciate that such design or modification practiced does not depart from the spirit and scope of the disclosure. Therefore, the scope of protection of the present disclosure is defined as the subject matter set forth in the appended claims.

1. A high electron mobility transistor device, comprising:
a substrate;
a superlattice buffer layer disposed over the substrate, wherein the superlattice buffer layer comprises a plurality of sets of alternating layers, and each set of alternating layers comprises at least one AlN layer and at least one AlₓGa₍₁₋ₓ₎N layer alternately arranged, wherein 0≤x<1;
a gradient buffer layer disposed over the substrate, wherein the gradient buffer layer comprises a plurality of Al_{y}Ga_{(1-y)}N layers, wherein 0≤y<1, a ratio of a thickness of the superlattice buffer layer to a thickness of the gradient buffer layer is from about 0.2 to about 0.75; and
a channel layer disposed over the gradient buffer layer.

2. The high electron mobility transistor device as claimed in claim 1, wherein the AlₓGa₍₁₋ₓ₎N layers have the same x value in each set of alternating layers.

3. The high electron mobility transistor device as claimed in claim 1, wherein the AlₓGa₍₁₋ₓ₎N layers have different x values for different sets of alternating layers.

4. The high electron mobility transistor device as claimed in claim 3, wherein the x values of the AlₓGa₍₁₋ₓ₎N layers of the set of alternating layers adjacent to the substrate are greater than the x values of the AlₓGa₍₁₋ₓ₎N layers of the set of alternating layers away from the substrate.

5. The high electron mobility transistor device as claimed in claim 1, wherein a thickness of the AlN layer ranges from 1 nm to 20 nm and a thickness of the AlₓGa₍₁₋ₓ₎N layer ranges from 5 nm to 100 nm in each set of alternating layers.

6. The high electron mobility transistor device as claimed in claim 1, wherein a ratio of a thickness of the AlₓGa₍₁₋ₓ₎N layer to a thickness of the AlN layer ranges from 3 to 10.

7. The high electron mobility transistor device as claimed in claim 1, wherein a thickness of each of the Al_{y}Ga_{(1-y)}N layers ranges from 50 nm to 500 nm.

8. The high electron mobility transistor device as claimed in claim 1, wherein a y value of the Al_{y}Ga_{(1-y)}N layer adjacent to the substrate is greater than a y value of the Al_{y}Ga_{(1-y)}N layer away from the substrate.

9. The high electron mobility transistor device as claimed in claim 1, wherein the gradient buffer layer is disposed over the superlattice buffer layer.

10. The high electron mobility transistor device as claimed in claim 1, further comprising a nucleation layer disposed between the substrate and the superlattice buffer layer, wherein the nucleation layer comprises aluminum nitride (AlN), aluminum gallium nitride (AlGaN), or a combination thereof.

11. The high electron mobility transistor device as claimed in claim 10, further comprising:
a barrier layer disposed over the channel layer; and
a source, a drain, a gate disposed over the barrier layer.

12. A method for forming high electron mobility transistor devices, comprising:
forming a substrate;
forming a superlattice buffer layer over the substrate, wherein the superlattice buffer layer comprises a plurality of sets of alternating layers, and each set of alternating layers comprises at least one AlN layer and at least one AlₓGa₍₁₋ₓ₎N layer alternately arranged, wherein 0≤x<1;
forming a gradient buffer layer over the substrate, wherein the gradient buffer layer comprises a plurality of Al_{y}Ga_{(1-y)}N layers, wherein 0≤y<1, a ratio of a thickness of the superlattice buffer layer to a thickness of the gradient buffer layer is from about 0.2 to about 0.75; and
forming a channel layer over the gradient buffer layer.

13. The method as claimed in claim 12, wherein the AlₓGa₍₁₋ₓ₎N layers have the same x value in each set of alternating layers.

14. The method as claimed in claim 12, wherein the AlₓGa₍₁₋ₓ₎N layers have different x values for different sets of alternating layers.

15. The method as claimed in claim 14, wherein the x values of the AlₓGa₍₁₋ₓ₎N layers of the set of alternating layers adjacent to the substrate are greater than the x values of the AlₓGa₍₁₋ₓ₎N layers of the set of alternating layers away from the substrate.

16. The method as claimed in claim 12, wherein in each set of alternating layers, a thickness of the AlN layer ranges from 1 nm to 20 nm, a thickness of the AlₓGa₍₁₋ₓ₎N layer ranges from 5 nm to 100 nm, and a ratio of the thickness of the AlₓGa₍₁₋ₓ₎N layer to the thickness of the AlN layer ranges from 3 to 10.

17. The method as claimed in claim 12, wherein a thickness of each of the Al_{y}Ga_{(1-y)}N layers ranges from 50 nm to 500 nm.

18. The method as claimed in claim 12, wherein a y value of the Al_{y}Ga_{(1-y)}N layer adjacent to the substrate is greater than a y value of the Al_{y}Ga_{(1-y)}N layer away from the substrate.

19. The method as claimed in claim 12, wherein the gradient buffer layer is formed over the superlattice buffer layer.

20. The method as claimed in claim 12, further comprising forming a nucleation layer between the substrate and the superlattice buffer layer, wherein the nucleation layer comprises aluminum nitride (AlN), aluminum gallium nitride (AlGaN), or a combination thereof.
